(19) United States
(12) Patent Application Publication
(10) Pub. No.: US 2025/0052805 A1
(43) Pub. Date: Feb. 13, 2025

(54) METHOD FOR CHECKING THE SWITCH-OFF CAPABILITY OF A MOSFET

(71) Applicant: Continental Automotive Technologies GmbH, Hannover (DE)

(72) Inventors: Erwin Kessler, Saulgau (DE); Christian Gil, Toulouse (FR)

(73) Assignee: Continental Automotive Technologies GmbH, Hannover (DE)

(21) Appl. No.: 18/722,915

(22) PCT Filed: Dec. 16, 2022
(86) PCT No.: PCT/DE2022/200303

§ 371 Date: Jun. 21, 2024

(30) Foreign Application Priority Data
Dec. 23, 2021 (DE) 10 2021 214 971.5

(51) Int. Cl. G01R 31/26; G01R 31/327; H02H 3/087

(52) U.S. Cl. CPC G01R 31/2621; G01R 31/2633; G01R 31/3277; H02H 3/087

(57) ABSTRACT

Disclosed is a method for checking the turn-off capability of an electronic fuse in the form of a MOSFET, said electronic fuse being used as an interrupter switch between a voltage supply and a control device, wherein the MOSFET is turned on during operation as intended and is operated in the linear region, wherein, for checking the turn-off capability, the gate-source voltage of the MOSFET is reduced by a predefined value until a predefined threshold value is reached and, after the threshold value has been reached, the gate-source voltage is increased again to the previous value for turning on the MOSFET, and wherein a check is made to ascertain whether the drain-source voltage of the MOSFET increases as the gate-source voltage is reduced.

In present-day power supply architectures of vehicles, electronic control devices that are supplied with current even during a parking mode of the vehicle are supplied directly from the 12 V vehicle battery. In this case, the cabling between battery and control devices is at present usually protected by fusible links.

Driven by the supply demand e.g. of autonomous driving, the fusible links are frequently being replaced by electronic fuses, often referred to as e-fuses.

The electronic fuses are typically realized by means of electronic switches in the form of MOSFETs. The MOSFET control can be part of an intelligent network switch or can be realized by means of specific integrated circuits (ICs) supplemented by discrete circuit blocks.

In this case, it is possible and customary for the electronic fuses to supply diagnosis information such as the current through the switch, the temperature of the switch and further useful information. All this information is predominantly made available while an electronic fuse is in the closed state. One item of information that is often missing is whether a closed electronic fuse can be opened if the situation would necessitate opening.

In the case of a fusible link the failure state of the fuse device is an open fuse, while in the case of an electronic fuse a defect of the switching element can result in a closed switch. This would have the effect that in the case of an event that would necessitate the opening of the fuse, this opening cannot be realized on account of the defect of the electronic fuse.

In principle, it would be possible to switch off an electronic fuse in specific situations in order to check whether the turn-off capability is still provided. In the case of some critical control devices that are supplied via an electronic fuse, interrupting the supply for a specific time is not allowed, however.

The data sheet concerning the integrated circuit VFN1048F from ST describes a control IC for a high-side switch with e-fuse protection for automotive applications.

The integrated circuit has a self-test for external FETs with regard to their capability of being able to be switched to the non-conducting state (stuck-on). For this purpose, the FET is switched off and the drain-source voltage of the FET is subsequently monitored by the integrated circuit. In this case, the self-test can be ended by a stop signal or as a result of a defined threshold value for the drain-source voltage being reached. In the latter case, the self-test is stopped if the drain-source voltage exceeds said threshold value.

However, the FET is switched off here as well.

The object of the invention is to specify a method for checking the turn-off capability of a MOSFET in which turning off the MOSFET is avoided.

The object is achieved by means of a method according to claim 1. Advantageous developments are specified in the dependent claims.

Accordingly, in a method for checking the turn-off capability of an electronic fuse in the form of a MOSFET, said electronic fuse being used as an interrupter switch between a voltage supply and a control device, wherein the MOSFET is turned on during operation as intended and is operated in the linear region, and wherein, for checking the turn-off capability, the gate-source voltage of the MOSFET is reduced by a predefined value until a predefined threshold value is reached and, after the threshold value has been reached, the gate-source voltage is increased again to the previous value for turning on the MOSFET, a check is made to ascertain whether the drain-source voltage (VDs) of the MOSFET increases as the gate-source voltage is reduced.

The electronic fuse realized by a MOSFET is thus not completely turned off. The MOSFET is only partially turned off during a specific test sequence. That means that the MOSFET is controlled from the so-called RDSon-controlled switching state into the saturation operating region by the gate-source control voltage of the MOSFET being reduced or the gate capacitance being discharged. Upon entry into the saturation operating region, the voltage drop across the load path of the MOSFET, that is to say the drain-source voltage thereof, increases significantly.

Changing to the saturation operating region affords the advantage that it is possible to attain the voltage drop within a small time window for quite a high output current range. A short test time and a small voltage drop reduce the thermal loading for the switching element. Moreover, it affords the advantage of offering the possibility of a fully integrated solution.

In one advantageous embodiment of the method, the MOSFET is controlled and checked by means of a control and diagnosis circuit controlled by a control unit.

In a further advantageous embodiment of the method, the gate-source voltage is reduced in time ranges in which the control device does not have a high current demand.

Normal operation is not adversely affected as a result.

The invention will be described in greater detail below on the basis of an exemplary embodiment with the aid of figures. In the figures here:

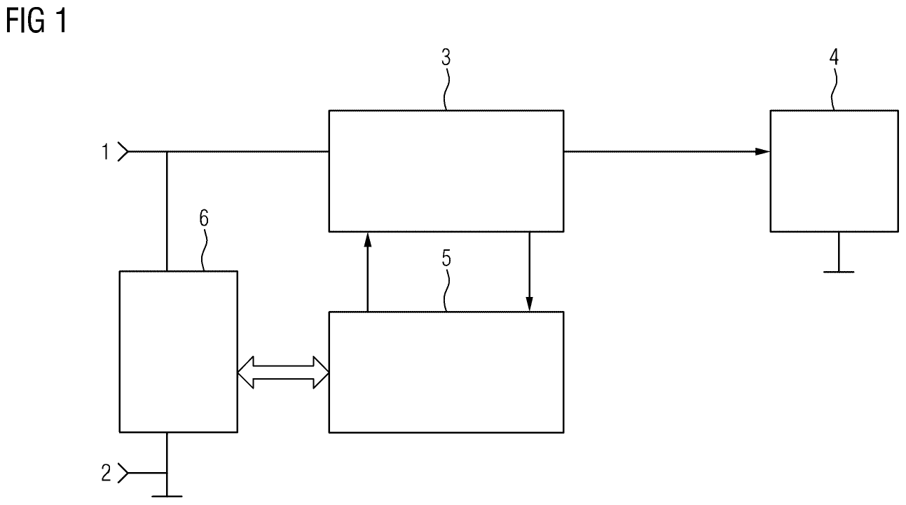

FIG. 1 shows a basic circuit diagram of a control device which is protected by means of an electronic fuse and which is supplied from a voltage supply source,

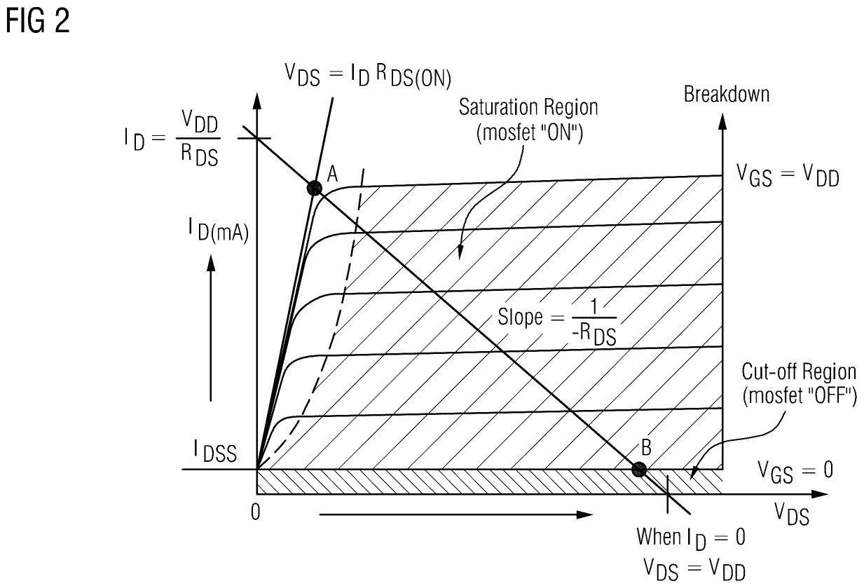

FIG. 2 shows a known family of characteristic curves of a MOSFET for elucidating the operating regions, and

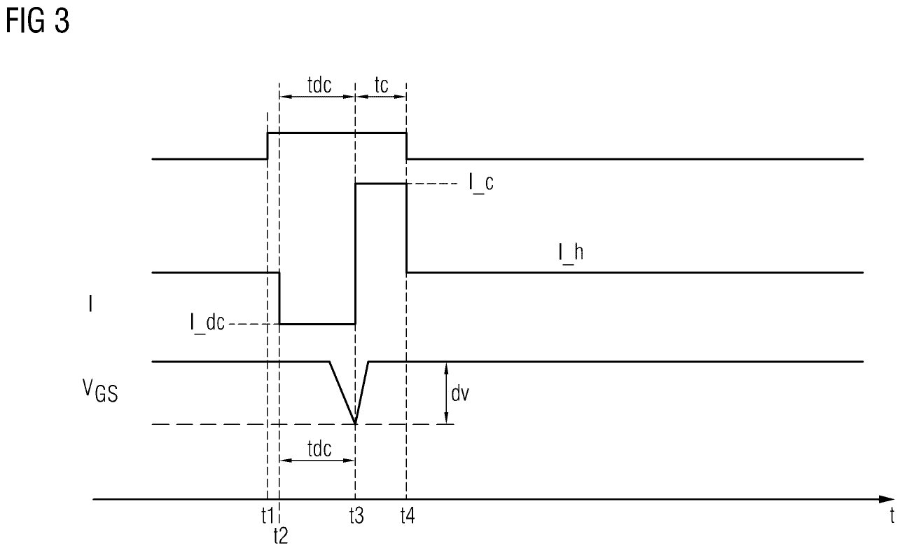

FIG. 3 shows a profile of the gate-source voltage and of the drain current of a MOSFET controlled according to the invention.

FIG. 1 schematically shows two connecting terminals 1, 2 for a voltage source, for example a 12-volt battery in a motor vehicle. The connecting terminal 1 for the positive pole of the voltage source is connected to a control device 4 via an electronic fuse 3.

The electronic fuse 3 is formed by a MOSFET and during normal operation, in which the control device 4 is supplied by the voltage source, is fully turned on in order to minimize the on-state resistance of the MOSFET-usually designated as R_{DSon}.

The control device 4 is of a type which must not be completely disconnected from the voltage supply, and so checking the turn-off capability of the MOSFET by completely opening the latter is out of the question.

In the exemplary embodiment illustrated, the MOSFET is controlled by a control and diagnosis circuit 5, which is in turn controlled by a control unit 6.

For elucidation, FIG. 2 illustrates the family of characteristic curves of a MOS field effect transistor with a load line. During normal operation, the MOSFET is controlled with a high gate-source voltage V_{GS}, such that its on-state resistance R_{DSon} becomes as small as possible. This is elucidated by the point A in FIG. 2. The transistor is operated in the so-called linear region since the voltage drop V_{DS} across its load path is proportional to the drain current I_{D}.

In a manner according to the invention, during a test phase that begins at the point in time t1 in the diagram in FIG. 3, the gate electrode capacitance begins to be discharged at a somewhat delayed point in time t2, this being indicated by a discharge current I_dc. After a certain time, the gate-source voltage V_{GS} begins to decrease until it reaches a predefined threshold value after a discharge time t_dc, said threshold value being lower than the normal gate-source voltage V_{GS} by a measure dV. The gate electrode capacitance is then charged again with a charging current I_c, as a result of which the gate-source voltage V_{GS} rises again until it reaches the initial value again after a charging time t_c.

As a result of the discharge of the gate electrode capacitance and the attendant reduction of the gate-source voltage V_{GS}, the operating region of the MOSFET moves into the hatched region of the family of characteristic curves illustrated in FIG. 2. As a result, the drain-source voltage V_{DS} of the MOSFET increases significantly, which can be detected, which is preferably done by means of the control and diagnosis circuit 5. This increase in the drain-source voltage V_{DS} is then an indication that the electronic fuse 3 realized as a MOSFET can be opened in a serious situation and is thus functional.

The turn-off capability test is carried out in a vehicle status with limited current demand at the output of the electronic fuse 3. This may be e.g. in the phase in which the supplied control device 4 is still in operation, but does not activate any current-consuming loads. In this status, the current consumption of the control device 4 provides for a rapid voltage drop phase during the switching capability test and limits the power loss of the MOSFET during the linear load.

Ideally, communication network-based power management defines events for the turn-off capability test on the basis of the gathered information about the vehicle status and the status of the supplied control devices.

1. A method for checking the turn-off capability of an electronic fuse in the form of a MOSFET, said electronic fuse being used as an interrupter switch between a voltage supply and a control device, comprising:
turning on the MOSFET during operation as intended,
operating the MOSFET in the linear region,
reducing the gate-source voltage of the MOSFET by a predefined value until a predefined threshold value is reached,
after the threshold value has been reached, increasing the gate-source voltage to a previous value for turning on the MOSFET, and
ascertaining whether the drain-source voltage of the MOSFET increases as the gate-source voltage is reduced.

2. The method as claimed in claim 1, wherein the MOSFET is controlled and checked by a control and diagnosis circuit controlled by a control unit.

3. The method as claimed in claim 1, wherein the gate-source voltage is reduced in time ranges in which the control device does not have a high current demand.

4. The method as claimed in claim 2, wherein the gate-source voltage is reduced in time ranges in which the control device does not have a high current demand.
